(19) United States
(12) Patent Application Publication
(10) Pub. No.: US 2009/0053018 A1
(43) Pub. Date: Feb. 26, 2009

(54) METHOD AND APPARATUS FOR TRANSFERRING SEMICONDUCTOR DEVICES IN TEST HANDLER

(76) Inventor: Jin-Hwan Lee, Cheonan-si (KR)

Correspondence Address: DALY, CROWLEY, MOFFORD & DURKEE, LLP, SUITE 301A, 354A TURNPIKE STREET, CANTON, MA, 02021-2714, US

(21) Appl. No.: 11/869,191

(22) Filed: Oct. 9, 2007

(30) Foreign Application Priority Data
Aug. 22, 2007 (KR) 10-2007-0084343

(51) Int. Cl. H01L 21/673

(52) U.S. Cl. 414/222.01

(57) ABSTRACT

In a method and an apparatus for transferring semiconductor devices between trays used for testing the semiconductor devices using a buffer tray for receiving the semiconductor devices, an x-pitch in a row direction of the buffer tray is adjusted by first and second driving sections to equalize with an x-pitch in a row direction of a test tray or a customer tray. The semiconductor devices are transferred among the test tray, the buffer tray and the customer tray by first and second picker systems. Thus, the time required to transfer the semiconductor devices may be shortened.

### CROSS-REFERENCE TO RELATED APPLICATIONS

This application claims priority under 35 USC §119 to Korean Patent Application No. 2007-84343, filed on Aug. 22, 2007 in the Korean Intellectual Property Office (KIPO), the contents of which are incorporated herein by reference in their entirety.

### BACKGROUND OF THE INVENTION

1. Field of the Invention

The present invention relates to a method and an apparatus for testing semiconductor devices. More particularly, the present invention relates to a method and an apparatus for transferring semiconductor devices in a test handler used to test semiconductor devices.

2. Description of the Related Art

Generally, semiconductor devices, such as volatile or non-volatile memory devices, system large-scale integration (LSI) devices, etc., are shipped after testing operating characteristics of the semiconductor devices.

A test handler transfers semiconductor devices into a test chamber to test the semiconductor devices. Particularly, semiconductor devices are transferred from a customer tray to a test tray via a buffer tray. Further, semiconductor devices that have been tested in the test chamber are transferred from a test tray to a customer tray via a buffer tray.

The test handler includes a picker system for transferring the semiconductor devices between the test tray and the customer tray. Examples of the picker system are disclosed in U.S. Pat. Nos. 6,761,526, 7,000,648, 7,023,197, etc.

Recently, to shorten the time required to transfer semiconductor devices, the picker system employs a plurality of pickers. Further, the picker system employs a pitch-adjusting device to equalize a pitch between the pickers with that of the test tray or the customer tray. However, shortening the time required to transfer the semiconductor devices has limitations because the weight of the pitch-adjusting device is increased as the number of the pickers is increased.

### SUMMARY OF THE INVENTION

Example embodiments of the present invention provide a method of transferring semiconductor devices capable of improving a transfer speed of the semiconductor devices in a test handler used for testing the semiconductor devices.

Further, example embodiments of the present invention provide an apparatus for transferring semiconductor devices capable of improving a transfer speed of the semiconductor devices in a test handler used for testing the semiconductor devices.

In a method of transferring semiconductor devices according to an aspect of the present invention, the semiconductor devices may be transferred between trays having a plurality of sockets for receiving the semiconductor devices. An x-pitch in a row direction of a buffer tray may be equalized with an x-pitch in a row direction of a first tray. The semiconductor devices may be transferred from the first tray to the buffer tray having the adjusted x-pitch.

In some example embodiments of the present invention, the buffer tray may include a plurality of pairs of unit buffer trays extending in a column direction of the buffer tray. The x-pitch of the buffer tray may be adjusted by adjusting a first x-pitch between the pairs of unit buffer trays and adjusting a second x-pitch between first unit buffer trays and second unit buffer trays in the pairs of unit buffer trays.

In some example embodiments of the present invention, each of the first and second unit buffer trays may include a plurality of sockets arranged in one column.

In some example embodiments of the present invention, the semiconductor devices may be picked up off the first tray by a picker system comprising a plurality of pickers. The pickers by which the semiconductor devices are held may be moved over the buffer tray. Then, the semiconductor devices may be received from the pickers into sockets of the buffer tray. A y-pitch in a column direction of the picker system may be equalized with a y-pitch in a column direction of the buffer tray while the pickers are moved over the buffer tray.

In some example embodiments of the present invention, the picker system may include a plurality of pairs of picker units extending in a row direction of the picker system. The y-pitch of the picker system may be adjusted by adjusting a first y-pitch between the pairs of picker units and adjusting a second y-pitch between first picker units and second picker units in the pairs of picker units.

In some example embodiments of the present invention, the buffer tray may include a plurality of unit buffer trays. Each of the unit buffer trays may include a plurality of sockets arranged in a plurality of columns.

In some example embodiments of the present invention, the x-pitch of the buffer tray may include a first x-pitch between the unit buffer trays and a second x-pitch between the sockets of each of the unit buffer trays. The x-pitch of the buffer tray may be the first x-pitch between the unit buffer trays. The semiconductor devices may be picked up off the first tray using a picker system comprising a plurality of pickers arranged in rows and columns. The picker system may have an x-pitch in a row direction of the picker system different from the second x-pitch of the buffer tray. The pickers by which the semiconductor devices are held may be moved over the buffer tray. Then, the semiconductor devices may be received from the pickers into sockets of the buffer tray while moving the pickers in the row direction of the buffer tray in a stepwise manner.

In some example embodiments of the present invention, the x-pitch of the buffer tray may be equalized with an x-pitch in a row direction of a second tray. Then, the semiconductor devices may be transferred from the buffer tray to the second tray.

In some example embodiments of the present invention, the semiconductor devices may be picked up off the first tray using pickers arranged in rows and columns. The pickers by which the semiconductor devices are held may be moved over the buffer tray. The semiconductor devices may be sequentially received into the buffer tray one row at a time while moving the buffer tray in a column direction of the buffer tray in a stepwise manner.

In an apparatus for transferring semiconductor devices according to another aspect of the present invention, the semiconductor devices may be transferred between trays having a plurality of sockets for receiving the semiconductor devices. The apparatus may include a buffer tray having a plurality of sockets arranged in rows and columns, a driving section connected to the buffer tray to adjust an x-pitch in a row direction of the buffer tray, and a picker system transferring the semiconductor devices from a first tray to the buffer tray.

In some example embodiments of the present invention, the buffer tray may include a plurality of pairs of unit buffer trays extending in a column direction of the buffer tray. The driving section may include a first driving section adjusting a first x-pitch between the pairs of unit buffer trays, and a second driving section adjusting a second x-pitch between first unit buffer trays and second unit buffer trays in the pairs of unit buffer trays.

In some example embodiments of the present invention, the first driving section may include at least one rack gear, a gearbox comprising at least one output gear engaged with the at least one rack gear, and a motor unit connected to the gearbox to provide a rotational force to the gearbox. The at least one rack gear may move at least one of the pairs of unit buffer trays in the row direction of the buffer tray to adjust the first x-pitch.

In some example embodiments of the present invention, the apparatus may further include first links connected to the first unit buffer trays, and second links connecting the second unit buffer trays and the first links. The first driving section may be connected to the first unit buffer trays or the second unit buffer trays.

In some example embodiments of the present invention, the second driving section may be connected to the first links or the second links and may apply a driving force to the first links or the second links to produce a relative movement between the first unit buffer trays and the second unit buffer trays.

In some example embodiments of the present invention, the picker system may include a plurality of pickers arranged in rows and columns to pick up the semiconductor device, and a picker-transferring section moving the pickers between the first tray and the buffer tray.

In some example embodiments of the present invention, an x-pitch in a row direction and a y-pitch in a column direction of the picker system may be equal to an x-pitch in a row direction and a y-pitch in a column direction of the first tray.

In some example embodiments of the present invention, the picker system may include a plurality of pairs of picker units picking up the semiconductor devices, and a picker-transferring section moving the pairs of picker units between the first tray and the buffer tray. Each of the pairs of picker units may include a first picker unit and a second picker unit. Each of the first and second picker units may include a plurality of pickers to pick up the semiconductor devices. The pairs of picker units may be arranged in a column direction of the picker system.

In some example embodiments of the present invention, the picker system may further include a picker-driving section adjusting a y-pitch in the column direction of the picker system.

In some example embodiments of the present invention, the picker-driving section may include a first picker-driving section adjusting a first y-pitch between the pairs of picker units, and a second picker-driving section adjusting a second y-pitch between first picker units and second picker units in the pairs of picker units.

In some example embodiments of the present invention, the first picker-driving section may include at least one rack gear connected to at least one of the pairs of picker units, a gear box comprising at least one output gear engaged with the at least one rack gear, and a motor unit connected to the gearbox to provide a rotational force to the gearbox. The at least one rack gear may move at least one of the pairs of picker units in the column direction of the picker system to adjust the first y-pitch.

In some example embodiments of the present invention, the picker system may include first links connected to the first picker units, and second links connecting the second picker units and the first links. The first picker-driving section may be connected to the first picker units or the second picker units.

In some example embodiments of the present invention, the second picker-driving section may be connected to the first links or the second links and may apply a driving force to the first links or the second links to produce a relative movement between the first picker units and the second picker units.

In some example embodiments of the present invention, the apparatus may further include a second picker system transferring the semiconductor devices from the buffer tray to a second tray.

In some example embodiments of the present invention, the second picker system may include a plurality of pickers arranged in rows and columns to pick up the semiconductor device. An x-pitch and a y-pitch of the second picker system may be equal to an x-pitch and a y-pitch of the second tray. A y-pitch of the buffer tray may be equal to the y-pitch of the second tray.

In some example embodiments of the present invention, the buffer tray may include a plurality of unit buffer trays extending in a column direction of the buffer tray the driving section may include a motor unit providing a rotational force, a gearbox connected to the motor unit and comprising at least one output gear, and at least one rack gear connected to at least one of the unit buffer trays and engaged with the at least one output gear to adjust the x-pitch of the buffer tray.

In accordance with the example embodiments of the present invention, an x-pitch of a buffer tray may be equalized with that of a test tray or a customer tray by first and second driving sections.

As a result, there is no need to adjust x-pitches of first and second picker systems while transferring semiconductor devices, and thus the time required to transfer the semiconductor devices may be shortened. Further, there is no need for additional devices for adjusting the x-pitches of the first and second picker systems, and thus the weight of the first and second picker systems may be reduced, thereby improving the structural stability of the test handler.

Further, a y-pitch of the first picker system may be adjusted by first and second picker-driving sections, and thus the time required to transfer the semiconductor devices may be shortened.

### BRIEF DESCRIPTION OF THE DRAWINGS

Example embodiments of the present invention will become readily apparent along with the following detailed description when considered in conjunction with the accompanying drawings, wherein:

FIG. 1 is a schematic view illustrating an apparatus for transferring semiconductor devices in accordance with an example embodiment of the present invention;

FIG. 2 is a perspective view illustrating a first driving section and a second driving section for adjusting an x-pitch of the buffer tray shown in FIG. 1;

FIG. 3 is a plan view illustrating the buffer tray shown in FIG. 1;

FIG. 4 is a perspective view illustrating the gearbox of the first driving section shown in FIG. 2;

FIG. 5 is a plan view illustrating the gearbox of the first driving section shown in FIG. 2;

FIG. 6 is a bottom view illustrating the first motor unit of the first driving section shown in FIG. 2;

FIGS. 7 to 9 are plan views illustrating a method of adjusting an x-pitch of a buffer tray using the first and second driving sections shown in FIG. 2;

FIG. 10 is a perspective view illustrating the first picker system shown in FIG. 1;

FIG. 11 is a schematic view illustrating a method of receiving semiconductor devices into a buffer tray;

FIG. 12 is a plan view illustrating another example of a first picker system;

FIG. 13 is a bottom view illustrating the first picker system shown in FIG. 12;

FIG. 14 is a plan view illustrating another example of first and second driving sections for adjusting an x-pitch of a buffer tray;

FIG. 15 is a plan view illustrating still another example of first and second driving sections for adjusting an x-pitch of a buffer tray;

FIG. 16 is plan view illustrating another example of a buffer tray;

FIG. 17 is a plan view illustrating a driving section for adjusting an x-pitch of a buffer tray;

FIGS. 18 and 19 are schematic views illustrating a method of transferring semiconductor devices using the buffer tray and the driving section shown in FIGS. 16 and 17;

FIG. 20 is a plan view illustrating another example of a driving section for adjusting an x-pitch of a buffer tray; and

FIG. 21 is a plan view illustrating still another example of a driving section for adjusting an x-pitch of a buffer tray.

### DESCRIPTION OF THE EMBODIMENTS

Embodiments of the invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present. In contrast, when an element is referred to as being “directly on” another element, there are no intervening elements present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first thin film could be termed a second thin film, and, similarly, a second thin film could be termed a first thin film without departing from the teachings of the disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Example embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

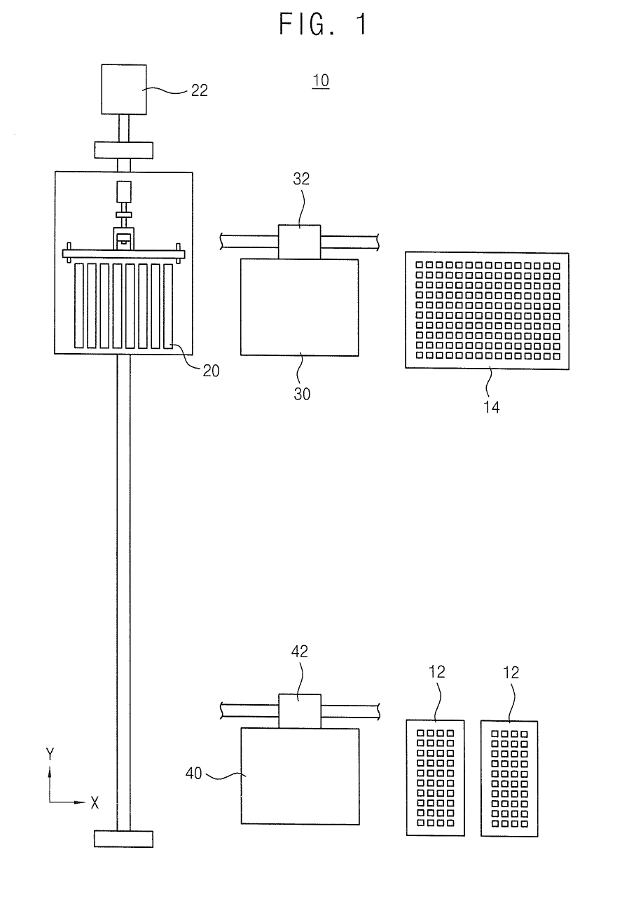

FIG. 1 is a schematic view illustrating an apparatus for transferring semiconductor devices in accordance with an example embodiment of the present invention.

Referring to FIG. 1, an apparatus 10 for transferring semiconductor devices according to an example embodiment of the present invention may be employed in a test handler used for testing the semiconductor devices. Particularly, the apparatus 10 may be used to transfer the semiconductor devices between a first tray and a second tray, for example, a customer tray 12 and a test tray 14, in the test handler.

Although not shown in figures, the apparatus 10 may include a buffer tray 20 movably disposed between the customer tray 12 and the test tray 14, and a first picker system 30 for transferring the semiconductor devices between the test tray 14 and the buffer tray 20. Further, the apparatus 10 may include a second picker system 40 for transferring the semiconductor between the buffer tray 20 and the customer tray 12.

Particularly, the buffer tray 20 may be movably disposed in a y-axis direction, and the first and second picker systems 30 and 40 may be movably disposed in x-axis and y-axis directions. For example, the buffer tray 20 may be moved by a buffer-transferring section 22, and the first and second picker systems 30 and 40 may be moved by first and second picker-transferring sections 32 and 42, respectively.

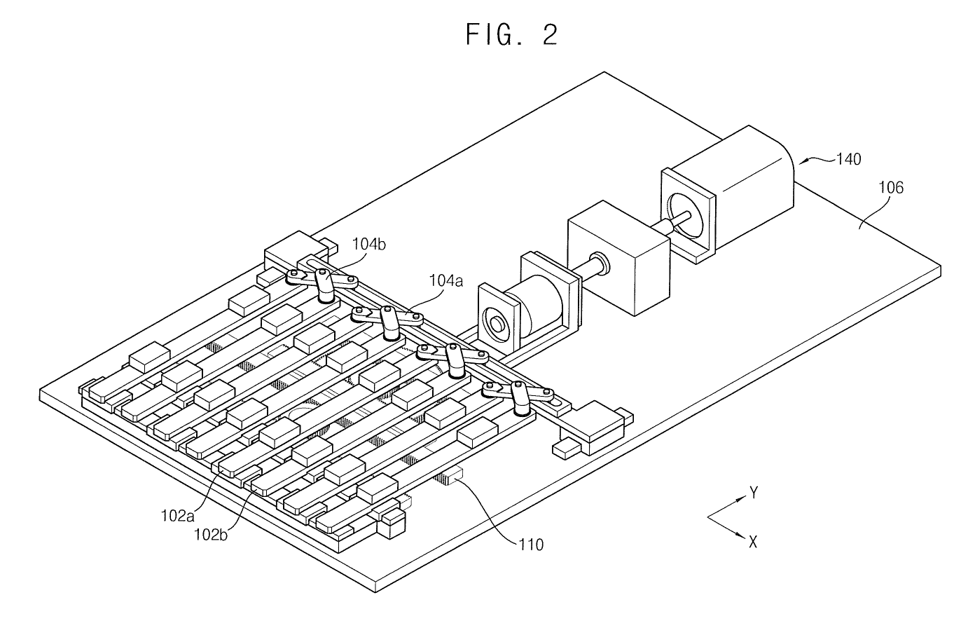

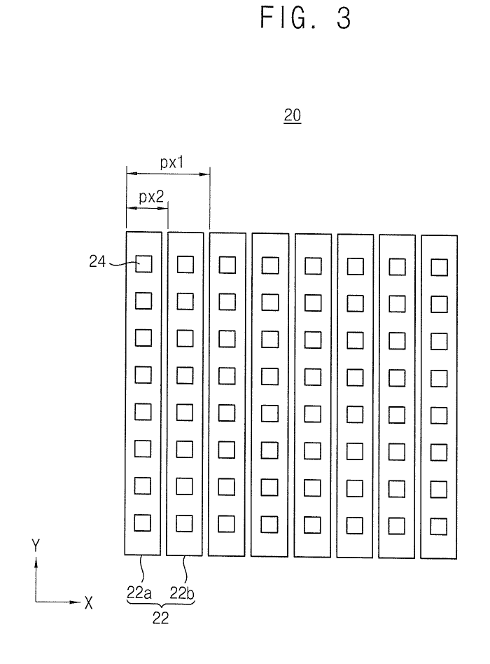

FIG. 2 is a perspective view illustrating a first driving section and a second driving section for adjusting an x-pitch of the buffer tray 20 shown in FIG. 1, and FIG. 3 is a plan view illustrating the buffer tray 20 shown in FIG. 1.

Referring to FIGS. 2 and 3, a pitch of the buffer tray 20 may be equalized with that of the test tray 14 or the customer tray 12.

The buffer tray 20 may include a plurality of pairs of unit buffer trays 22. Each of the pairs of unit buffer trays 22 may include a first unit buffer tray 22a and a second unit buffer tray 22b. For example, the buffer tray 20 may include four pairs of unit buffer trays 22.

Each of the first and second unit buffer trays 22a and 22b may have a plurality of sockets 24 arranged in one column to receive the semiconductor devices. The first and second unit buffer trays 22a and 22b may be parallel to one another. For example, each of the first and second unit buffer trays 22a and 22b may have eight sockets 24 as shown in FIG. 3. However, the number of the sockets 24 of the first and second unit buffer trays 22a and 22b may vary as occasion demands. Here, the plurality of pairs of unit buffer trays 22 may be arranged in a row direction (x-axis direction) substantially perpendicular to a column direction (y-axis direction), that is, an extension direction of the first and second unit buffer trays 22a and 22b.

The first and second unit buffer trays 22a and 22b may each be disposed on first supports 102a and second supports 102b. The first and second supports 102a and 102b may extend in the column direction of the buffer tray 20 beneath the first and second unit buffer trays 22a and 22b.

First links 104a may be connected to end portions of the first supports 102a, and second links 104b may be connected to end portions of the second supports 102b. Further, the second links 104b may be connected to the first links 104a. As shown in FIG. 2, the second links 104b may be connected to central portions of the first links 104a. Alternatively, end portions of the first links 104a and end portions of the second links 104b may be connected with each other. Further, the end portions of the first links 104a may be connected to central portions of the second links 104b.

An x-pitch in the row direction of the buffer tray 20 may be adjusted by a first driving section 110 and a second driving section 140. Particularly, the x-pitch of the buffer tray 20 may include a first x-pitch px1 between the pairs of unit buffer trays 22 and a second x-pitch px2 between the first unit buffer trays 22a and the second unit buffer trays 22b. The first and second x-pitches px1 and px2 may be adjusted by the first and second driving sections 110 and 140, respectively. The first and second driving sections 110 and 140 may be disposed on a base plate 106.

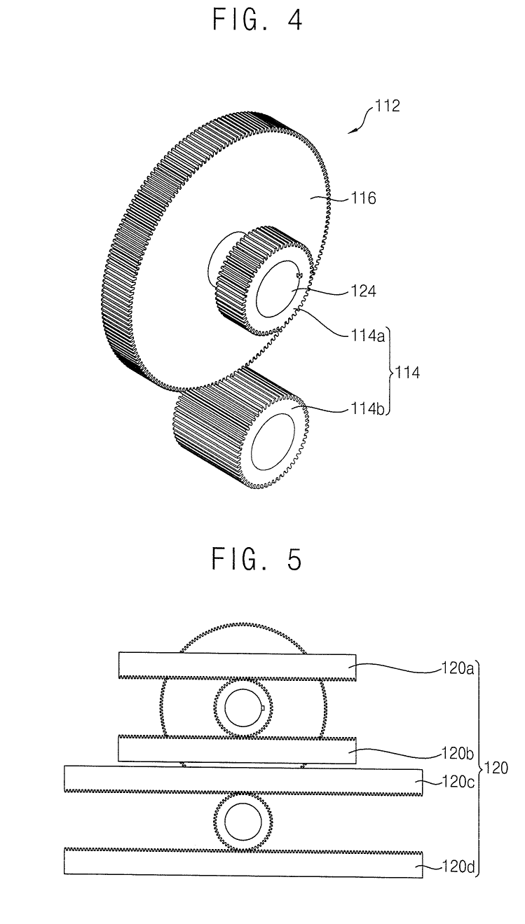

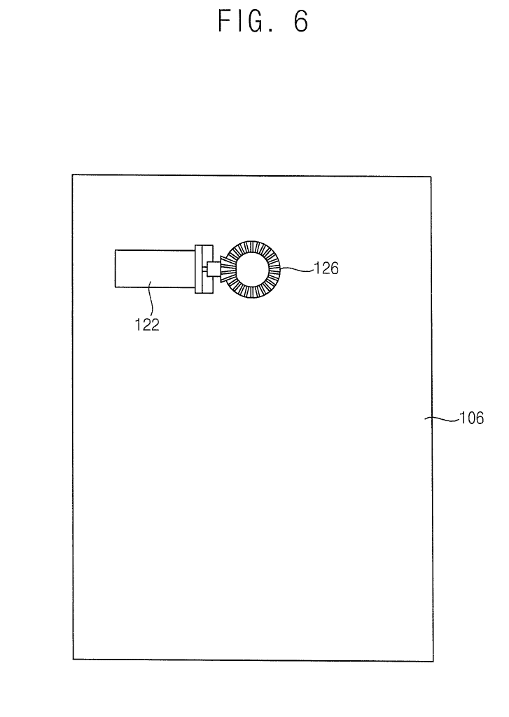

FIG. 4 is a perspective view illustrating the gearbox of the first driving section 110 shown in FIG. 2, FIG. 5 is a plan view illustrating the gearbox of the first driving section 110 shown in FIG. 2, and FIG. 6 is a bottom view illustrating the first motor unit of the first driving section 110 shown in FIG. 2.

Referring to FIGS. 4 to 6, the first driving section 110 may include a gearbox 112 including at least one output gear rotatably disposed on an upper surface of the base plate 106, a plurality of rack gears 120 engaged with the output gear, and a first motor unit 122 connected to the gearbox 112 to provide a rotational force to the gearbox 112.

For example, four rack gears 120a, 120b, 120c and 120d may be disposed on the upper surface of the base plate 106. The four rack gears 120a, 120b, 120c and 120d may be engaged with two pinion gears 114a and 114b serving as the output gears. Particularly, a first pinion gear 114a may be connected to a driving shaft 124 of the first motor unit 122, and may be further engaged with a first rack gear 120a and a second rack gear 120b opposite to each other. Further, a second pinion gear 114b may be engaged with a driving gear 116 that is connected to the driving shaft 124 of the first motor unit 122, and may be further engaged with a third rack gear 120c and a fourth rack gear 120d opposite to each other.

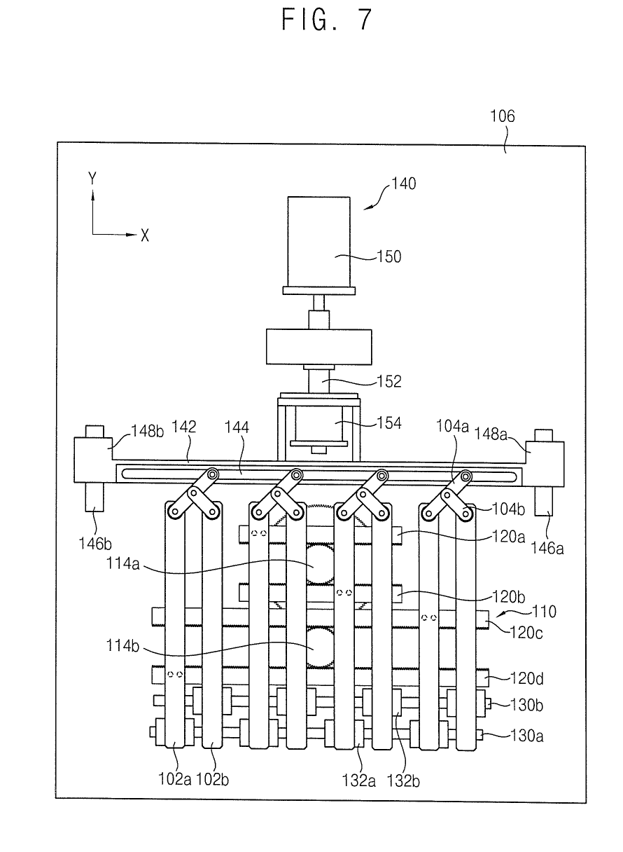

FIGS. 7 to 9 are plan views illustrating a method of adjusting the x-pitch of the buffer tray 20 using the first and second driving sections 110 and 140 shown in FIG. 2.

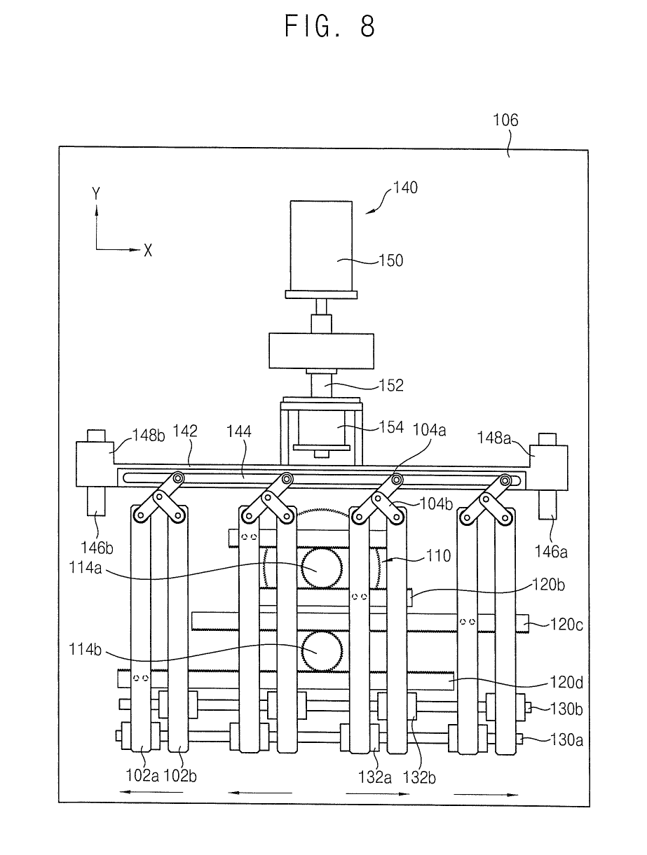

Referring to FIGS. 7 and 8, the first rack gear 120a and the second rack gear 120b may be connected to inner pairs of unit buffer trays 22 through the first and second supports 102a and 102b. The third rack gear 120c and the fourth rack gear 120d may be connected to outer pairs of unit buffer trays 22 through the first and second supports 102a and 102b. Particularly, first pairs of unit buffer trays 22 disposed on a left side of the buffer tray 20 in FIGS. 7 and 8 may be connected to the first and fourth rack gears 120a and 120d. Second pairs of unit buffer trays 22 disposed on a right side of the buffer tray 20 in FIGS. 7 and 8 may be connected to the second and third rack gears 120b and 120c. Thus, the first and second pairs of unit buffer trays 22 may be moved in opposite directions to each other with respect to a central point of the buffer tray 20 by rotating the first and second pinion gears 114a and 114b as shown in FIG. 8.

The first, second, third and fourth rack gears 120a, 120b, 120c and 120d may be connected to the first unit buffer trays 22a through the first supports 102a. Alternatively, the first, second, third and fourth rack gears 120a, 120b, 120c and 120d may be connected to the second unit buffer trays 22b through the second supports 102b.

Although not shown in the figures, a plurality of guide members may be disposed on the base plate 106 to guide the first, second, third and fourth rack gears 120a, 120b, 120c and 120d in the row direction of the buffer tray 20.

A ratio between rotational speeds of the first and second pinion gears 114a and 114b may be 1:3 so as to equalize intervals between the first unit buffer trays 22a with one another. Particularly, the first and second pinion gears 114a and 114b may have a pitch circle smaller than that of the driving gear 116. The diameter of the driving gear 116 may be three times larger than that of the second pinion gear 114b, and the diameter of the first pinion gear 114a may be substantially the same as that of the second pinion gear 114b. As a result, the first x-pitch px1 between the pairs of unit buffer trays 22 may be adjusted by rotating the first and second pinion gears 114a and 114b.

Meanwhile, because the first unit buffer trays 22a are connected to the second unit buffer trays 22b by the first and second links 104a and 104b, the second x-pitch px2 between the first and second unit buffer trays 22a and 22b may be evenly maintained while adjusting the first x-pitch px1.

As described above, the gearbox 112 includes two pinion gears 114a and 114b and four rack gears 120a, 120b, 120c and 120d. However, the gearbox 112 may include three or more pinion gears having different rotational speeds, and the first driving section 110 may include a plurality of rack gears engaged with the pinion gears. That is, the numbers of the pinion gears and the rack gears may vary according to the number of the first unit buffer trays 22a.

Further, when the buffer tray 20 includes two pairs of unit buffer trays 22, the first driving section 110 may include one pinion gear and two rack gears.

Referring to FIG. 6, the driving shaft 124 may extend through the base plate 106, and the first motor unit 122 may be disposed on a lower surface of the base plate 106. The first motor unit 122 may be connected with the driving shaft 124 by bevel gears 126. Alternatively, the first motor unit 122 may be directly connected with the driving shaft 124.

Referring again to FIG. 7, at least one guide member, which extends in the row direction of the buffer tray 20, may be disposed on the upper surface of the base plate 106 to guide the first and second supports 102a and 102b in the row direction of the buffer tray 20, that is, an x-pitch direction of the buffer tray 20. For example, a first guide rail 130a and a second guide rail 130b may be disposed on the base plate 106. The first and second guide rails 130a and 130b may extend in the row direction of the buffer tray 20. The first and second supports 102a and 102b may be coupled to the first and second guide rails 130a and 130b by first ball blocks 132a and second ball blocks 132b. Alternatively, the first and second supports 102a and 102b may be guided by one guide rail in the row direction.

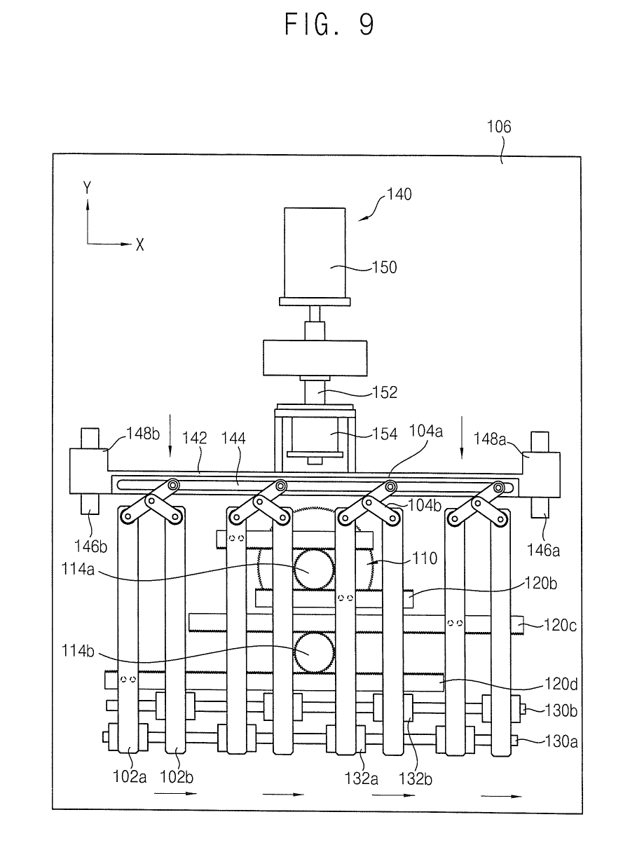

Referring to FIGS. 8 and 9, the second driving section 140 may be disposed on the upper surface of the base plate 106 and may be connected with the end portions of the first links 104a. Particularly, the second driving section 140 may apply a driving force to the first links 104a to adjust the second x-pitch px2 between the first unit buffer trays 22a and the second unit buffer trays 22b. Thus, a relative movement may be produced between the first unit buffer trays 22a and the second unit buffer trays 22b.

The end portions of the first links 104a may be guided by a guide member in the row direction of the buffer tray 20. For example, a guide bar 142 may be adjacent to the buffer tray 20, and may be extend in the row direction of the buffer tray 20 on the base plate 106. The guide bar 142 may have a slot 144 that extends in the row direction of the buffer tray 20, and a plurality of rollers (not shown) may be disposed in the slot 144. The end portions of the first links 104a may be connected to the rollers.

Both side portions of the guide bar 142 may be coupled to a third guide rail 146a and a fourth guide rail 146b, which extend in the column direction of the buffer tray 20 on the base plate 106, through a third ball block 148a and a fourth ball block 148b. That is, the second driving section 140 may be connected to the end portions of the first links 104a through the guide bar 142 and the rollers. The guide bar 142 may be moved in the column direction of the buffer tray 20 by the second driving section 140, and thus the first links 104a may rotate around axes located at the end portions of the first supports 102a, and the second links 104b may rotate around axes located at the central portions of the first links 104a. As a result, the second unit buffer trays 22b may be relatively moved in the row direction of the buffer tray 20, that is, the x-pitch direction of the buffer tray 20, with respect to the first unit buffer trays 22a. The second x-pitch px2 of the buffer tray 20 may be adjusted by adjusting a moving distance of the guide bar 142.

As shown in FIGS. 7 to 9, after adjusting the first x-pitch px1, the second x-pitch px2 is adjusted. However, after adjusting the second x-pitch px2, the first x-pitch px1 may be adjusted according to circumstances.

Alternatively, the end portions of the first links 104a may be guided by a plurality of ball blocks and a guide rail in the row direction. For example, a fifth guide rail may be adjacent to the buffer tray 20, and a plurality of fifth ball blocks may be movably coupled to the fifth guide rail. The end portions of the first links 104a may be connected to the fifth ball blocks.

The second driving section 140 may be connected to the guide bar 142 on the upper surface of the base plate 106. Particularly, the second driving section 140 may include a second motor unit 150, a ball screw 152 connected with a rotation shaft of the second motor unit 150, and a ball nut 154 connected to the guide bar 142. The ball screw 152 may extend through the ball nut 154. A rotational force of the second motor unit 150 may be applied to the guide bar 142 through the ball screw 152 and the ball nut 154.

Alternatively, various types of reciprocating devices may be selectively used as the second driving section 140. For example, a reciprocating device including a cam and a spring, a pneumatic or hydraulic cylinder, etc. may be used as the second driving section 140.

Although not shown in the figures, the adjustment of the x-pitch of the buffer tray 20 may be inaccurately performed due to backlash of the first and second driving sections 110 and 140. To improve the accuracy in the adjustment of the x-pitch, the first unit buffer trays 22a and the second unit buffer trays 22b may be connected with one another by a plurality of springs. For example, the first unit buffer trays 22a and the second unit buffer trays 22b may be connected by first coil springs. Further, the first unit buffer trays 22a disposed on one side of the buffer tray 20 may be connected to each other by a second coil spring(s), and the first unit buffer trays 22a disposed on another side of the buffer tray 20 may be connected to each other by a third coil spring(s).

FIG. 10 is a perspective view illustrating the first picker system 30 shown in FIG. 1.

Referring to FIG. 10, the first picker system 30 may include a plurality of pickers 202 arranged in rows and columns. The pickers 202 may be movably disposed by the picker-transferring section 32. Although not shown in the figures, the pickers 202 may be used to pick up the semiconductor devices using a vacuum force. Each of the pickers 202 may be configured to move in a vertical direction, that is, in a z-axis direction.

Particularly, the first picker system 30 may include a plurality of picker units 200. Each of the picker units 200 may include a plurality of pickers 202 arranged in a row direction of the first picker system 30. For example, each of the picker units 200 may include a bracket 204 extending in the row direction (x-axis direction), and the pickers 202 may be mounted to the bracket 204 in the vertical direction.

Further, the first picker system 30 may include a first picker base 206 to which the picker units 200 are mounted in a column direction (y-axis direction) of the first picker system 30. The first picker base 206 may be connected to the first picker-transferring section 32. Although not shown in the figures, the first picker-transferring section 32 may be configured to move the pickers 202 in the x-axis and y-axis directions. For example, the first picker-transferring section 32 may be configured using a linear motor, a ball screw, a ball block, a linear motion guide, etc.

An x-pitch in the row direction and a y-pitch in the column direction of the first picker system 30 may be equal to an x-pitch in a row direction and a y-pitch in a column direction of the test tray 14. Thus, the first picker system 30 may pick up the semiconductor devices off the test tray 14 in one operation. For example, the first picker system 30 may pick up sixty-four or thirty-two semiconductor devices off the test tray 14 in one operation.

The picker 202 may be moved over the buffer tray 20 by the first picker-transferring section 32 after the semiconductor devices are picked up. Here, the x-pitch of the buffer tray 20 may be equalized with the x-pitch of the test tray 14 by the first and second driving sections 110 and 140.

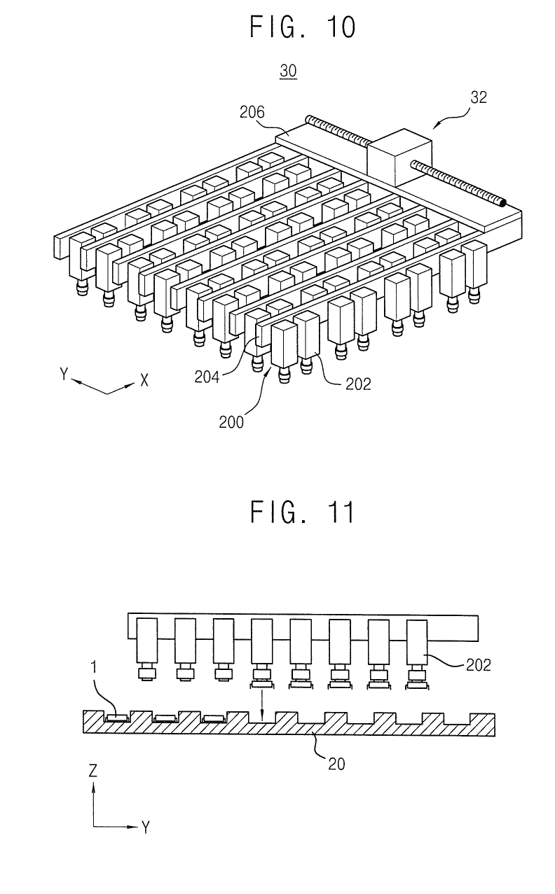

FIG. 11 is a schematic view illustrating a method of receiving the semiconductor devices into the buffer tray 20.

Referring to FIG. 11, the semiconductor devices 1 may be sequentially received one row at a time from the first picker system 30 into the buffer tray 20 because a y-pitch of the buffer tray 20 is different from the y-pitch of the test tray 14. Particularly, the buffer tray 20 may be moved in the column direction, that is, in the y-axis direction in a stepwise manner. The semiconductor devices 1 held by the pickers 202 of the first picker system 30 may be received into the sockets of the buffer tray 20 one row at a time while the buffer tray 20 is moved in the stepwise manner. Alternatively, the first picker system 30 may be moved in the y-axis direction in a stepwise manner, and the semiconductor devices 1 may be received into the buffer tray 20 in the meantime.

The x-pitch of the buffer tray 20 may be equalized with an x-pitch in a row direction of the customer tray 12 after the semiconductor devices 1 are received into the buffer tray 20. Further detailed descriptions of the method of equalizing the x-pitch of the buffer tray 20 with the x-pitch of the customer tray 12 will be omitted because the method is similar to that already described with reference to FIGS. 7 to 9.

Further, the buffer tray 20 may be moved by the buffer-transferring section 22 to a position adjacent to the customer tray 12. The x-pitch of the buffer tray 20 may be adjusted during the movement. Alternatively, the x-pitch of the buffer tray 20 may be adjusted after or before the movement.

After the adjustment of x-pitch and the movement of the buffer tray 20, the semiconductor devices 1 may be transferred by the second picker system 40 from the buffer tray 20 to the customer tray 12.

The second picker system 40 may include a plurality of pickers arranged in rows and columns. An x-pitch in a row direction and a y-pitch in a column direction of the second picker system 40 may be equal to an x-pitch in a row direction and a y-pitch in a column direction of the customer tray 12. Further detailed descriptions of the second picker system 40 will be omitted because the second picker system 40 is similar to the first picker system 30 already described with reference to FIG. 10.

Further, the y-pitch of the buffer tray 20 may be equal to the y-pitch of the customer tray 12. Thus, the semiconductor devices 1 may be picked up off the buffer tray 20 in one operation and may be received into the customer tray 12 in one operation.

As described above, although used to transfer the semiconductor devices 1 from the test tray 14 to the customer tray 12, the method and the apparatus 10 may also be used to transfer the semiconductor devices 1 from the customer tray 12 to the test tray 14 in a similar, if not the same, manner.

In accordance with the example embodiment of the present invention as described above, the first x-pitch px1 between the first unit buffer trays 22a may be adjusted by the first driving section 110, and the second x-pitch px2 between the first unit buffer trays 22a and the second unit buffer trays 22b may be adjusted by the second driving section 140. As a result, the x-pitch of the buffer tray 20 may be equalized to that of the test tray 14 or the customer tray 12. Thus, there is no need to adjust the x-pitches of the first and second picker systems 30 and 40 for transferring the semiconductor devices, thereby shortening the time required to transfer the semiconductor devices among the test tray 14, the buffer tray 20 and the customer tray 12. Further, the weights of the first and second picker systems 30 and 40 may be reduced, thereby improving the structural stability of the test handler and increasing the numbers of the pickers of the first and second picker systems 30 and 40.

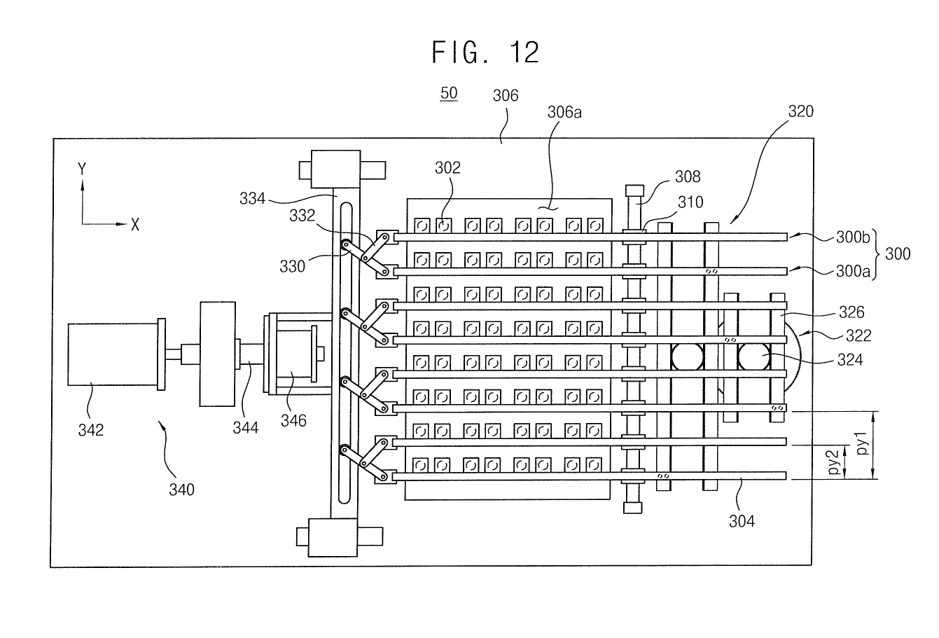

FIG. 12 is a plan view illustrating another example of the first picker system, and FIG. 13 is a bottom view illustrating the first picker system shown in FIG. 12.

Referring to FIGS. 12 and 13, a first picker system 50 may include a plurality of pickers 302 arranged in rows and columns. Particularly, the first picker system 50 may include a plurality of pairs of picker units 300 extending in a row direction (x-axis direction) of the first picker system 50. Each of the pairs of picker units 300 may include a first picker unit 300a and a second picker unit 300b. Each of the first and second picker units 300a and 300b may include a bracket 304 extending in the row direction and a plurality of pickers 302 mounted to the bracket 304 in a vertical direction. The first and second picker units 300a and 300b may be arranged in a column direction of the first picker system 50, and the pickers 302 may be disposed in the vertical direction through a central hole 306a of a picker base 306.

The brackets 304 may be connected to a guide member disposed on an upper surface of the picker base 306. For example, a first guide rail 308, which extends in the column direction, may be disposed on the upper surface of the picker base 306. The brackets 304 may be connected to the first guide rail 308 by a plurality of first ball blocks 310. Alternatively, a plurality of guide members, for example, a plurality of guide rails, may be disposed to guide the first and second picker units 300a and 300b in the column direction (y-axis direction) on the picker base 306.

A first picker-driving section 320 and a second picker-driving section 340 may be disposed to adjust a y-pitch in the column direction of the first picker system 50 on the picker base 306. For example, the first picker-driving section 320 may be provided to adjust a first y-pitch py1 between the pairs of picker units 300. The second picker-driving section 340 may be provided to adjust a second y-pitch py2 between the first picker units 300a and the second picker units 300b in the pairs of picker units 300.

For example, the first picker system 50 may include four pairs of picker units 300. The first picker-driving section 320 may include a gearbox 322 including two pinion gears 324, four rack gears 326 engaged with the pinion gears 324 to adjust the first y-pitch py1 between the four pairs of picker units 300, and a third motor unit 328 connected to the gearbox 322 to provide a rotational force.

The first picker units 300a and the second picker units 300b may be connected to third links 330 and fourth links 332. End portions of the third links 330 may be connected to a guide bar 334 extending in the column direction, and end portions of the fourth links 332 may be connected to central portions of the third links 330.

The second picker-driving section 340 may be provided to move the guide bar 334 in the row direction (x-axis direction) of the first picker system 50. Particularly, the second picker-driving section 340 may include a fourth motor unit 342 for providing a rotational force, a ball screw 344 connected to the fourth motor unit 342, a ball nut 346 connected to the guide bar 334, etc. The ball screw 344 may extend 10 through the ball nut 346.

Further detailed descriptions of a method of adjusting the y-pitch of the first picker system 50 using the first and second picker-driving sections 320 and 340 will be omitted because these are similar to those already described with reference to FIGS. 7 to 9.

An x-pitch of the first picker system 50 may be equal to the x-pitch of the test tray 14, and the y-pitch of the first picker system 50 may be equalized with the y-pitch of the test tray 14 by the first and second picker-driving sections 320 and 340. Thus, the first picker system 50 may pick up the semiconductor devices off the test tray 14 in one pick-up operation.

The pickers 302 may be moved over the buffer tray 20 by the first picker-transferring section. Here, the x-pitch of the buffer tray 20 may be equalized with x-pitch of the test tray 14 by the first and second driving sections 110 and 140. Further, the y-pitch of the first picker system 50 may be equalized with the y-pitch of the buffer tray 20 by the first and second picker-driving sections 320 and 340. Thus, the first 25 picker system 50 may receive the semiconductor devices held by the pickers 302 into the sockets of the buffer tray 20 in one unloading operation.

The weight of the first picker system 50 may be increased due to the first and second picker-driving sections 320 and 340. However, the time required to transfer the semiconductor devices may be remarkably shortened because the semiconductor devices may be transferred by one pick-up operation and one unloading operation.

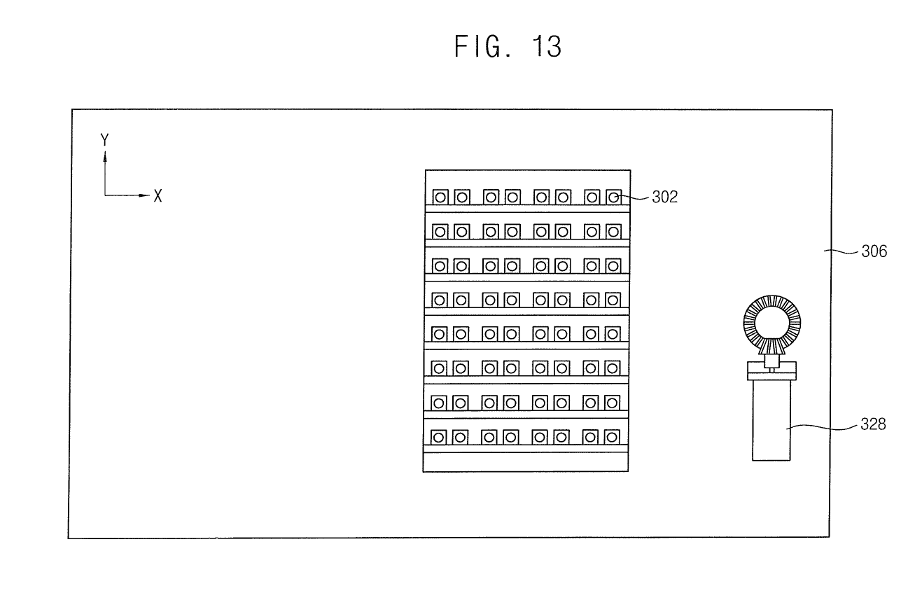

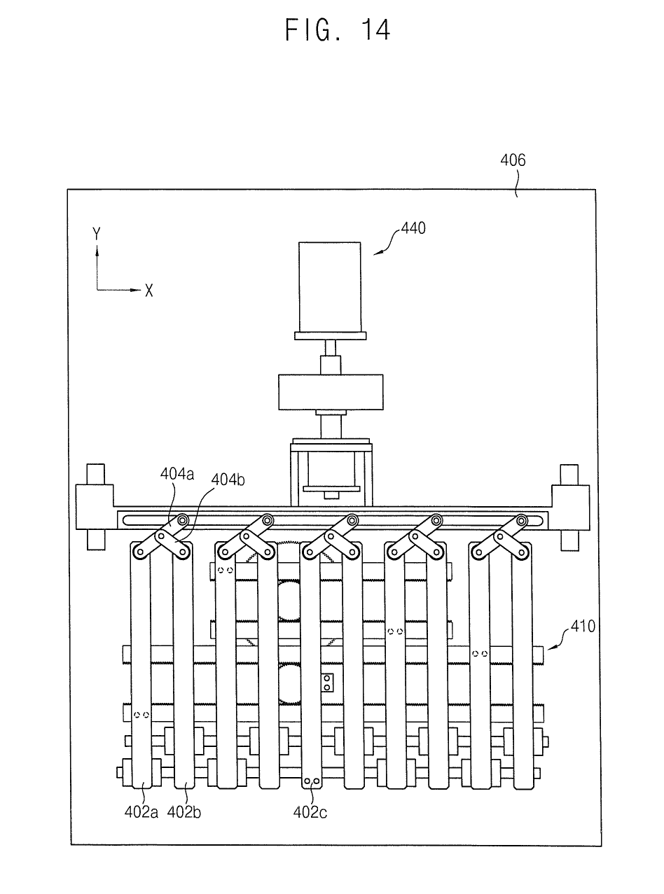

FIG. 14 is a plan view illustrating another example of first and second driving sections for adjusting an x-pitch of a buffer tray.

Referring to FIG. 14, a buffer tray may include a plurality of pairs of unit buffer trays. Each of the pairs of unit buffer trays may include a first unit buffer tray and a second unit buffer tray. For example, the buffer tray may include five pairs of unit buffer trays. Further detailed descriptions of the pairs of unit buffer trays will be omitted because these elements are similar to those already described with reference to FIGS. 2 to 9.

The first and second unit buffer trays may each be disposed on first and second supports 402a and 402b. The first and second supports 402a and 402b may extend in a column direction of the buffer tray beneath the first and second unit buffer trays.

First links 404a may be connected to end portions of the first supports 402a. Second links 404b may be connected to end portions of the second supports 402b. The second links 404b may be connected with the first links 404a.

A first x-pitch between the pairs of unit buffer trays may be adjusted by a first driving section 410, and a second x-pitch between the first unit buffer trays and the second unit buffer trays may be adjusted by a second driving section 440. The first driving section 410 may include at least one pinion gear and at least one rack gear. For example, the first driving section 410 may include two pinion gears and four rack gears. Further detailed descriptions of the first and second supports 402a and 402b, the first and second links 404a and 404b, and the first and second driving sections 410 and 440 will be omitted because these elements are similar to those already described with reference to FIGS. 2 to 9.

Meanwhile, a central pair of unit buffer trays adjacent to a central point of the buffer tray may be fixed on an upper surface of a base plate 406, and remaining pairs of unit buffer trays, except for the central pair of unit buffer trays, may be connected to the first driving section 410. That is, a first support 402c connected to a first unit buffer tray of the central pair may be mounted on the base plate 406. For example, when the first unit buffer tray of the central pair is fixed on the base plate 406, the first driving section 410 may be connected to remaining first unit buffer trays. Alternatively, when a second unit buffer tray of the central pair is fixed on the base plate 406, the first driving section 410 may be connected to remaining second unit buffer trays.

As a result, the rack gears of the first driving section 410 may move the remaining pairs of unit buffer trays, which are disposed on both sides with respect to the central pair of unit buffer trays, in opposite directions to each other, thereby adjusting the first x-pitch between the pairs of unit buffer trays.

Particularly, a ratio between rotational speeds of a first pinion gear and a second pinion gear of the first driving section 410 may be 1:2 so as to equalize intervals between the first unit buffer trays with one another. As a result, the first x-pitch between the pairs of unit buffer trays may be adjusted.

Alternatively, when the buffer tray includes three pairs of unit buffer trays, the first driving section 410 may include one pinion gear and two rack gears.

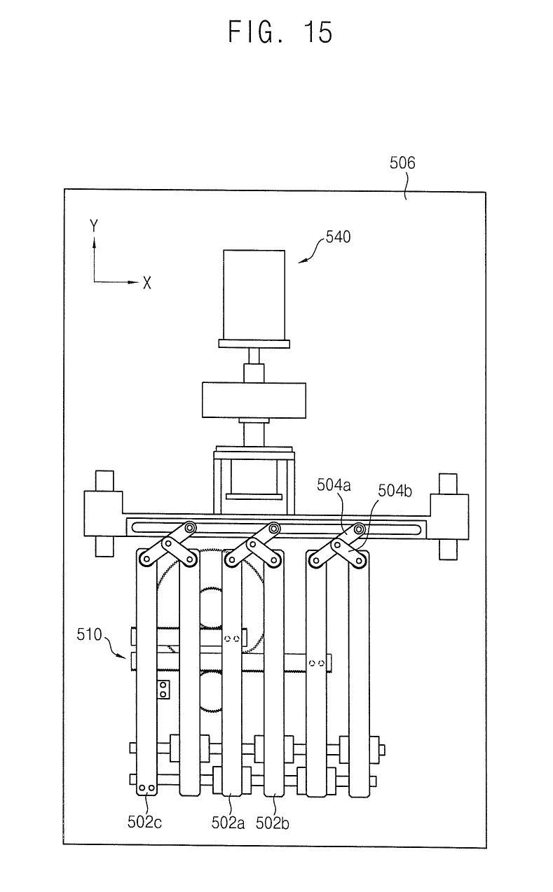

FIG. 15 is a plan view illustrating still another example of first and second driving sections for adjusting an x-pitch of a buffer tray.

Referring to FIG. 15, a buffer tray may include a plurality of pairs of unit buffer trays. Each of the pairs of unit buffer trays may include a first unit buffer tray and a second unit buffer tray. For example, the buffer tray may include three pairs of unit buffer trays. Further detailed descriptions of the pairs of unit buffer trays will be omitted because these elements are similar to those already described with reference to FIGS. 2 to 9.

The first and second unit buffer trays may each be disposed on first and second supports 502a and 502b. The first and second supports 502a and 502b may extend in a column direction of the buffer tray beneath the first and second unit buffer trays.

First links 504a may be connected to end portions of the first supports 502a. Second links 504b may be connected to end portions of the second supports 502b. The second links 504b may be connected with the first links 504a.

A first x-pitch between the pairs of unit buffer trays may be adjusted by a first driving section 510. A second x-pitch between the first unit buffer trays and the second unit buffer trays may be adjusted by a second driving section 540. The first driving section 510 may include at least one pinion gear and at least one rack gear. For example, the first driving section 510 may include two pinion gears and two rack gears. Further detailed descriptions of the first and second supports 502a and 502b, the first and second links 504a and 504b, and the first and second driving sections 510 and 540 will be omitted because these elements are similar to those already described with reference to FIGS. 2 to 9.

Meanwhile, an outermost pair of unit buffer trays of the buffer tray may be fixed on an upper surface of a base plate 506, and remaining pairs of unit buffer trays may be connected to the first driving section 510. For example, when an outermost support 502c connected to a first unit buffer tray of the outermost pair is mounted on the base plate 506, the first driving section 510 may be connected to remaining first unit buffer trays. Alternatively, when a second unit buffer tray of the outermost pair is fixed on the base plate 506, the first driving section 510 may be connected to remaining second unit buffer trays.

As a result, the rack gears of the first driving section 510 may move the remaining pairs of unit buffer trays in an x-pitch direction (x-axis direction) of the buffer tray, thereby adjusting the first x-pitch between the pairs of unit buffer trays.

Particularly, a ratio between rotational speeds of a first pinion gear and a second pinion gear of the first driving section 510 may be 1:2 so as to equalize intervals between the first unit buffer trays with one another. As a result, the first x-pitch between the pairs of unit buffer trays may be adjusted.

Alternatively, when the buffer tray includes two pairs of unit buffer trays, the first driving section 510 may include one pinion gear and one rack gear.

FIG. 16 is plan view illustrating another example of a buffer tray.

Referring to FIG. 16, a buffer tray 70 may include a plurality of unit buffer trays 72. Each of the unit buffer trays 72 may include a plurality of sockets arranged in a plurality of columns. For example, each of the unit buffer trays 72 may include a plurality of sockets 74a and 74b arranged in two columns. Here, an x-pitch between sockets in the each of the unit buffer trays 72 may be equal to that of the customer tray or the test tray.

FIG. 17 is a plan view illustrating a driving section for adjusting an x-pitch of a buffer tray.

Referring to FIG. 17, a buffer tray may include a plurality of unit buffer trays. Each of the unit buffer trays may include a plurality of sockets arranged in a plurality of columns, for example, in two columns, as shown in FIG. 16. The buffer tray may include an even-number of unit buffer trays. For example, the buffer tray may include four unit buffer trays as shown in FIG. 16, and each of the unit buffer trays may include first sockets arranged in a column direction and second sockets arranged in parallel with the first sockets.

An x-pitch in a row direction of the buffer tray between the unit buffer trays may be adjusted by a driving section 610 connected to the unit buffer trays. The driving section 610 may include a gearbox including at least one output gear, a plurality of rack gears engaged with the output gear, and a motor unit for providing a rotational force. For example, the driving section 610 may adjust the x-pitch of the buffer tray using two pinion gears 612 serving as the output gears and four rack gears 614. Here, the unit buffer trays and the rack gears 614 may be connected to each other by supports 602 that are disposed on a base plate 606.

The driving section 610 may move the unit buffer trays, which are disposed on both sides with respect to a central point of the buffer tray, in opposite directions to each other so as to adjust the x-pitch of the buffer tray. Further descriptions of the driving section 610 will be omitted because the driving section 610 is similar to the first driving section 110 already described with reference to FIGS. 2 to 9.

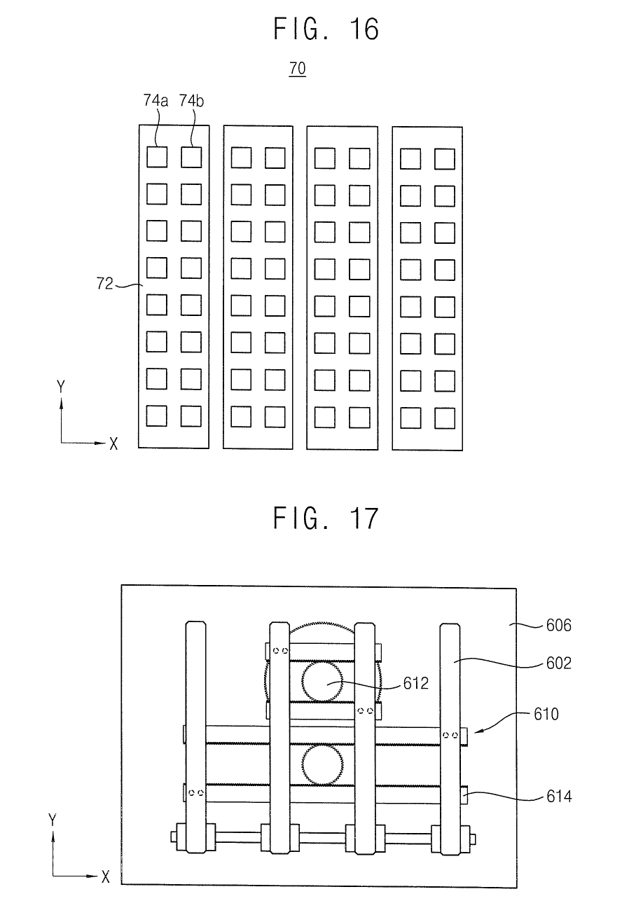

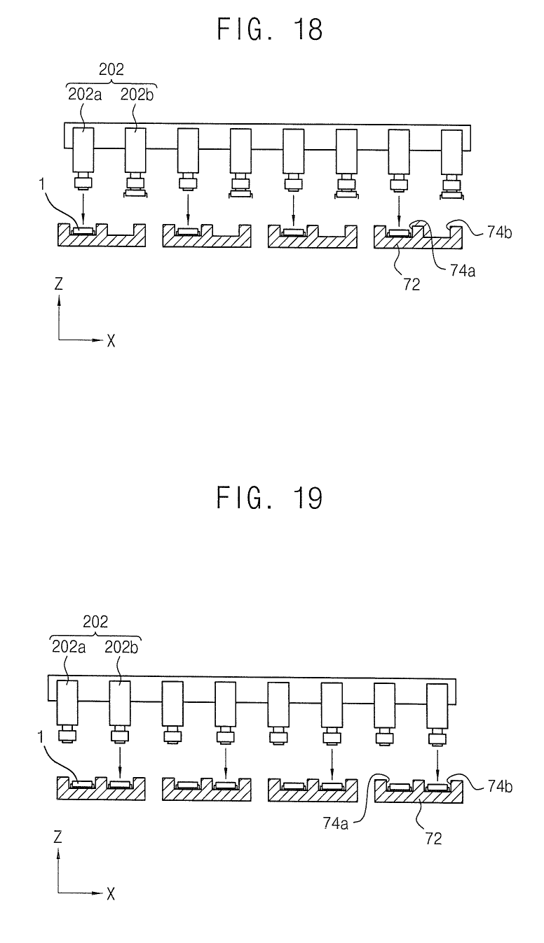

FIGS. 18 and 19 are schematic views illustrating a method of transferring semiconductor devices using the buffer tray and the driving section shown in FIGS. 16 and 17.

Referring to FIGS. 1,18 and 19, semiconductor devices 1 received in the test tray 14 may be picked up off the test tray 14 by the pickers 202 of the first picker system 30. Here, the x-pitch and the y-pitch of the pickers 202 may be equal to the x-pitch and the y-pitch of the test tray 14.

The first picker system 30 may be moved over the buffer tray 70 after the semiconductor devices 1 are picked up. Here, the x-pitch of the buffer tray 70 may be equalized with the x-pitch of the test tray 14. Particularly, an x-pitch between the unit buffer trays 72 may be equalized with an x-pitch between sockets of odd-numbered columns or even-numbered columns of the test tray 14. Pickers of odd-numbered columns 202a of the first picker system 30 may be moved over the first sockets 74a of the unit buffer trays 72, and the semiconductor devices 1 held by the sockets of odd-numbered columns 202a may then be received in the first sockets 74a.

The first picker system 30 may be moved in the row direction (x-axis direction) such that pickers of even-numbered columns 202b of the first picker system 30 are placed over the second sockets 74b of the unit buffer trays 72, and the semiconductor devices 1 held by the sockets of even-numbered columns 202b may then be received in the second sockets 74b.

FIG. 20 is a plan view illustrating another example of a driving section for adjusting an x-pitch of a buffer tray.

Referring to FIG. 20, a buffer tray may include a plurality of unit buffer trays. Each of the unit buffer trays may include a plurality of sockets arranged in a plurality of columns, for example, in two columns, as shown in FIG. 16. The buffer tray may include an odd number of unit buffer trays. For example, the buffer tray may include five unit buffer trays, and each of the unit buffer trays may include first sockets arranged in a column direction and second sockets arranged in parallel with the first sockets.

A driving section 710 may be connected to the unit buffer trays to adjust an x-pitch in a row direction between the unit buffer trays. The driving section 710 may include a gearbox including at least one output gear, a plurality of rack gears engaged with the output gear, and a motor unit for providing a rotational force. For example, the driving section 710 may adjust the x-pitch of the buffer tray using two pinion gears 712 serving as the output gears and four rack gears 714. Here, the unit buffer trays and the rack gears 714 may be connected to each other by supports 702 that are disposed on a base plate 706.

The driving section 710 may move the unit buffer trays, which are disposed on both sides with respect to a central unit buffer tray of the buffer tray, in opposite directions to each other so as to adjust the x-pitch of the buffer tray. Further detailed descriptions of the driving section 710 will be omitted because the driving section 710 is similar to the first driving section already described with reference to FIG. 14.

Further, descriptions of a method of transferring semiconductor devices using the buffer tray and the driving section 710 will be omitted because these are similar to those already described with reference to FIGS. 18 and 19.

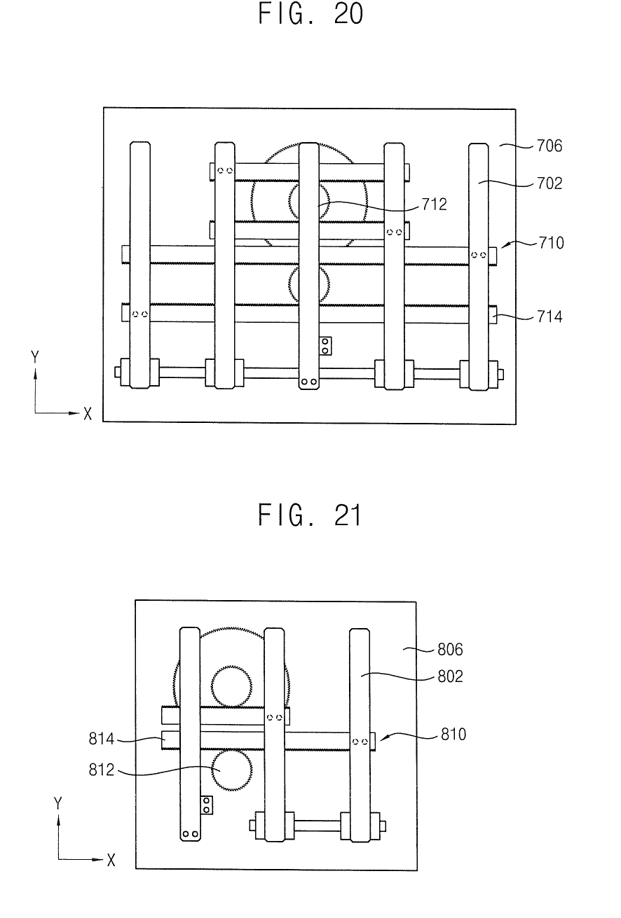

FIG. 21 is a plan view illustrating still another example of a driving section for adjusting an x-pitch of a buffer tray.

Referring to FIG. 21, a buffer tray may include a plurality of unit buffer trays.

Each of the unit buffer trays may include a plurality of sockets arranged in a plurality of columns, for example, in two columns, as shown in FIG. 16. For example, the buffer tray may include three unit buffer trays, and each of the unit buffer trays may include first sockets arranged in a column direction and second sockets arranged in parallel with the first sockets.

A driving section 810 may be connected to the unit buffer trays to adjust an x-pitch in a row direction between the unit buffer trays. The driving section 810 may include a gearbox including at least one output gear, at least one rack gear engaged with the at least one output gear, and a motor unit for providing a rotational force. For example, the driving section 810 may adjust the x-pitch of the buffer tray using two pinion gears 812 serving as the output gears and two rack gears 814. Here, the unit buffer trays and the rack gears 814 may be connected to each other by supports 802 that are disposed on a base plate 806.

The driving section 810 may move remaining unit buffer trays, except for an outermost unit buffer tray, in an x-pitch direction of the buffer tray to adjust the x-pitch of the buffer tray. Further detailed descriptions of the driving section 810 will be omitted because the driving section 810 is similar to the first driving section already described with reference to FIG. 15. Further, descriptions of a method of transferring semiconductor devices using the buffer tray and the driving section 810 will be omitted because these are similar to those already described with reference to FIGS. 18 and 19.

In accordance with the example embodiments of the present invention as described above, an x-pitch of a buffer tray may be adjusted by a first driving section including at least one pinion gear and at least one rack gear and a second driving section for moving links so that the x-pitch of the buffer tray may be equalized with that of a test tray or a customer tray.

Thus, there is no need to adjust x-pitches of first and second picker systems while transferring semiconductor devices, thereby shortening the time required to transfer the semiconductor devices. Further, there is no need for additional devices to adjust the x-pitches of the first and second picker systems, thereby reducing the weight of the first and second picker systems and improving the structural stability of a test handler.

Additionally, a y-pitch of the first picker system may be adjusted by first and second picker-driving sections, and thus the time required to transfer the semiconductor devices may be shortened.

Although the example embodiments of the present invention have been described, it is understood that the present invention should not be limited to these example embodiments but various changes and modifications can be made by those skilled in the art within the spirit and scope of the present invention as hereinafter claimed.

What is claimed is:

1. A method of transferring semiconductor device between trays having a plurality of sockets for receiving the semiconductor devices, comprising:
adjusting an x-pitch in a row direction of a buffer tray to equalize with an x-pitch in a row direction of a first tray; and
transferring the semiconductor devices from the first tray to the buffer tray.

2. The method of claim 1, wherein the buffer tray comprises a plurality of pairs of unit buffer trays extending in a column direction of the buffer tray, and wherein adjusting the x-pitch of the buffer tray comprises:
adjusting a first x-pitch between the pairs of unit buffer trays; and
adjusting a second x-pitch between first unit buffer trays and second unit buffer trays in the pairs of unit buffer trays.

3. The method of claim 2, wherein each of the first and second unit buffer trays comprises a plurality of sockets arranged in one column.

4. The method of claim 1, wherein transferring the semiconductor devices to the buffer tray comprises:
picking up the semiconductor devices off the first tray using a picker system comprising a plurality of pickers;
moving the pickers by which the semiconductor devices are held over the buffer tray; and
receiving the semiconductor devices from the pickers into sockets of the buffer tray,
and wherein a y-pitch in a column direction of the picker system is equalized with a y-pitch in a column direction of the buffer tray while moving the pickers over the buffer tray.

5. The method of claim 4, wherein the picker system comprises a plurality of pairs of picker units extending in a row direction of the picker system,
and wherein the y-pitch of the picker system is adjusted by adjusting a first y-pitch between the pairs of picker units and adjusting a second y-pitch between first picker units and second picker units in the pairs of picker units.

6. The method of claim 1, wherein the buffer tray comprises a plurality of unit buffer trays, and wherein each of the unit buffer trays comprises a plurality of sockets arranged in a plurality of columns.

7. The method of claim 6, wherein the x-pitch of the buffer tray comprises a first x-pitch between the unit buffer trays and a second x-pitch between the sockets of each of the unit buffer trays,
and wherein adjusting the x-pitch of the buffer tray comprises adjusting the first x-pitch between the unit buffer trays,
and wherein transferring the semiconductor devices to the buffer tray comprises:
picking up the semiconductor devices off the first tray using a picker system comprising a plurality of pickers arranged in rows and columns, wherein the picker system has an x-pitch in a row direction of the picker system different from the second x-pitch of the buffer tray;
moving the pickers by which the semiconductor devices are held over the buffer tray; and
receiving the semiconductor devices from the pickers into sockets of the buffer tray while moving the pickers in the row direction of the buffer tray in a stepwise manner.

8. The method of claim 1, further comprising:
adjusting the x-pitch of the buffer tray to equalize with an x-pitch in a row direction of a second tray; and
transferring the semiconductor devices from the buffer tray to the second tray.

9. The method of claim 1, wherein transferring the semiconductor devices to the buffer tray comprises:
picking up the semiconductor devices off the first tray using pickers arranged in rows and columns;
moving the pickers by which the semiconductor devices are held over the buffer tray; and
sequentially receiving the semiconductor devices into the buffer tray one row at a time while moving the buffer tray in a column direction of the buffer tray in a stepwise manner.

10. An apparatus for transferring semiconductor devices between trays having a plurality of sockets for receiving the semiconductor devices, comprising:
a buffer tray having a plurality of sockets arranged in rows and columns;
a driving section connected to the buffer tray to adjust an x-pitch in a row direction of the buffer tray; and
a picker system transferring the semiconductor devices from a first tray to the buffer tray.

11. The apparatus of claim 10, wherein the buffer tray comprises a plurality of pairs of unit buffer trays extending in a column direction of the buffer tray, and wherein the driving section comprises:
a first driving section adjusting a first x-pitch between the pairs of unit buffer trays; and
a second driving section adjusting a second x-pitch between first unit buffer trays and second unit buffer trays in the pairs of unit buffer trays.

12. The apparatus of claim 11, wherein the first driving section comprises:
at least one rack gear;
a gearbox comprising at least one output gear engaged with the at least one rack gear; and
a motor unit connected to the gearbox to provide a rotational force to the gearbox,
and wherein the at least one rack gear moves at least one of the pairs of unit buffer trays in the row direction of the buffer tray to adjust the first x-pitch.

13. The apparatus of claim 11, further comprising:
first links connected to the first unit buffer trays; and
second links connecting the second unit buffer trays and the first links,
wherein the first driving section is connected to the first unit buffer trays or the second unit buffer trays.

14. The apparatus of claim 13, wherein the second driving section is connected to the first links or the second links and applies a driving force to the first links or the second links to produce a relative movement between the first unit buffer trays and the second unit buffer trays.

15. The apparatus of claim 10, wherein the picker system comprises:
a plurality of pickers arranged in rows and columns to pick up the semiconductor device; and
a picker-transferring section moving the pickers between the first tray and the buffer tray.

16. The apparatus of claim 15, wherein an x-pitch in a row direction and a y-pitch in a column direction of the picker system are equal to an x-pitch in a row direction and a y-pitch in a column direction of the first tray.

17. The apparatus of claim 10, wherein the picker system comprises:
a plurality of pairs of picker units picking up the semiconductor devices; and
a picker-transferring section moving the pairs of picker units between the first tray and the buffer tray,
and wherein each of the pairs of picker units comprises a first picker unit and a second picker unit; each of the first and second picker units comprises a plurality of pickers to pick up the semiconductor devices; and the pairs of picker units are arranged in a column direction of the picker system.

18. The apparatus of claim 17, wherein the picker system further comprises a picker-driving section adjusting a y-pitch in the column direction of the picker system.

19. The apparatus of claim 18, wherein the picker-driving section comprises:
a first picker-driving section adjusting a first y-pitch between the pairs of picker units; and
a second picker-driving section adjusting a second y-pitch between first picker units and second picker units in the pairs of picker units.

20. The apparatus of claim 19, wherein the first picker-driving section comprises:
at least one rack gear connected to at least one of the pairs of picker units;
a gear box comprising at least one output gear engaged with the at least one rack gear; and
a motor unit connected to the gearbox to provide a rotational force to the gearbox,
and wherein the at least one rack gear moves at least one of the pairs of picker units in the column direction of the picker system to adjust the first y-pitch.

21. The apparatus of claim 19, wherein the picker system comprises:
first links connected to the first picker units; and
second links connecting the second picker units and the first links,
and wherein the first picker-driving section is connected to the first picker units or the second picker units.

22. The apparatus of claim 21, wherein the second picker-driving section is connected to the first links or the second links and applies a driving force to the first links or the second links to produce a relative movement between the first picker units and the second picker units.

23. The apparatus of claim 10, further comprising a second picker system transferring the semiconductor devices from the buffer tray to a second tray.

24. The apparatus of claim 23, wherein the second picker system comprises a plurality of pickers arranged in rows and columns to pick up the semiconductor device,
and wherein an x-pitch and a y-pitch of the second picker system are equal to an x-pitch and a y-pitch of the second tray, and a y-pitch of the buffer tray is equal to the y-pitch of the second tray.

25. The apparatus of claim 10, wherein the buffer tray comprises a plurality of unit buffer trays extending in a column direction of the buffer tray,
and wherein the driving section comprises:
a motor unit providing a rotational force;
a gearbox connected to the motor unit and comprising at least one output gear; and
at least one rack gear connected to at least one of the unit buffer trays and engaged with the at least one output gear to adjust the x-pitch of the buffer tray.
